(19) United States
(12) Patent Application Publication
(10) Pub. No.: US 2026/0198193 A1
(43) Pub. Date: Jul. 9, 2026

(54) ELECTRONIC DEVICE WITH PER COLOR DRIVING VOLTAGE LINES

(71) Applicant: SAMSUNG DISPLAY CO., LTD., YONGIN-SI (KR)

(72) Inventors: JONGYEOP AN, YONGIN-SI (KR); YOUNGWAN SEO, YONGIN-SI (KR); JUNKI JEONG, YONGIN-SI (KR)

(21) Appl. No.: 19/371,242

(22) Filed: Oct. 28, 2025

(30) Foreign Application Priority Data
Jan. 9, 2025 (KR) 10-2025-0003182

(51) Int. Cl. H10K 59/131; H10D 30/67; H10D 86/60; H10K 59/121; H10K 59/123; H10K 59/35

(52) U.S. Cl. CPC H10K 59/131; H10D 30/6731; H10D 86/60; H10K 59/1213; H10K 59/123; H10K 59/353

(57) ABSTRACT

An electronic device for displaying an image includes a first color pixel, a second color pixel, and a third color pixel that receive a first driving voltage, a second driving voltage, and a third driving voltage, respectively, a first vertical bus line, a second vertical bus line, and a third vertical bus line that transfer the first driving voltage, the second driving voltage, and the third driving voltage, respectively, and a first horizontal bus line, a second horizontal bus line, and a third horizontal bus line that connect the first vertical bus line, the second vertical bus line, and the third vertical bus line to the first color pixel, the second color pixel, and the third color pixel, respectively.

### CROSS-REFERENCE

This application claims priority under 35 U.S.C. § 119 to Korean Patent Application No. 10-2025-0003182, filed on Jan. 9, 2025 in the Korean Intellectual Property Office, the disclosure of which is incorporated by reference herein in its entirety.

### FIELD

Embodiments of the present disclosure generally relate to electronic devices for displaying images, and more particularly relate to electronic devices that may provide driving voltages of different voltage levels for different colors of pixels, respectively.

### INTRODUCTION

Multimedia electronic devices, such as televisions, mobile telephones, tablet computers, navigation devices, game machines, and the like, may display images. These and like electronic devices generate images and provide the generated images to users through a display screen.

A display screen may include a plurality of pixels. Each of the plurality of pixels may include a light-emitting element and may display an image by controlling a current flowing through the light-emitting element. Each pixel uses a voltage to provide the current to the light-emitting element.

### SUMMARY

Embodiments of the present disclosure include an electronic device for providing driving voltages having different voltage levels for different colors of pixels, respectively. In an embodiment, the respective driving voltages provided for the respective colors of pixels may be optimized, such as to minimize power consumption.

According to an embodiment, an electronic device for displaying a multi-color image may include a first bus line configured to supply a first driving voltage; a second bus line configured to supply a second driving voltage different than the first driving voltage; a first color pixel connected to the first bus line and configured to receive the first driving voltage and emit a first color of the multi-color image; and a second color pixel connected to the second bus line and configured to receive the second driving voltage and emit a second color of the multi-color image different than the first color.

In an embodiment, the first driving voltage may include a first high voltage and the second driving voltage may include a second high voltage.

In an embodiment, the electronic device may further include a third bus line configured to supply a third high voltage different than the second high voltage; and a third color pixel connected to the third bus line and configured to receive the third high voltage and emit a third color of the multi-color image different than each of the first color and the second color.

In an embodiment, the first bus line may include a first vertical bus line configured to transfer the first high voltage and a first horizontal bus line configured to connect the first vertical bus line to the first color pixel. The second bus line may include a second vertical bus line configured to transfer the second high voltage and a second horizontal bus line configured to connect the second vertical bus line to the second color pixel. The third bus line may include a third vertical bus line configured to transfer the third high voltage and a third horizontal bus line configured to connect the third vertical bus line to the third color pixel.

In an embodiment, the first horizontal bus line, the second horizontal bus line, and the third horizontal bus line may extend in a first direction and may be spaced apart from each other in a second direction different from the first direction.

In an embodiment, the first vertical bus line, the second vertical bus line, and the third vertical bus line may extend in the second direction and may be spaced apart from each other in the first direction.

In an embodiment, each of the first horizontal bus line, the second horizontal bus line, and the third horizontal bus line may extend in a first direction. At least a portion of the first horizontal bus line and at least a portion of the second horizontal bus line may be disposed to overlap each other when viewed from above a plane, and the first horizontal bus line and the third horizontal bus line may be spaced apart from each other in a second direction different from the first direction.

In an embodiment, the first vertical bus line, the second vertical bus line, and the third vertical bus line may extend in the second direction and may be spaced apart from each other in the first direction.

In an embodiment, the first high voltage, the second high voltage, and the third high voltage may have different voltage levels.

In an embodiment, each of the first color pixel, the second color pixel, and the third color pixel may include a fifth transistor including a first electrode, a second electrode, and a gate electrode, the first electrode being connected to a corresponding one of a first high voltage line, a second high voltage line, and a third high voltage line that receive the first high voltage, the second high voltage, and the third high voltage, respectively, a first transistor that may include a gate electrode and that may be connected between the second electrode of the fifth transistor and a first node, a sixth transistor that may include a gate electrode and that may be connected between the first node and a second node, and a light-emitting element connected between the second node and a low voltage line.

In an embodiment, the first color pixel may further include a fourth transistor including a first electrode connected to a first initialization voltage line, a second electrode connected to the second node, and a gate electrode.

In an embodiment, each of the second color pixel and the third color pixel may further include a fourth transistor including a first electrode connected to a second initialization voltage line, a second electrode connected to the second node, and a gate electrode.

In an embodiment, a first initialization voltage provided to the first initialization voltage line and a second initialization voltage provided to the second initialization voltage line may have different voltage levels.

According to an embodiment, an electronic device may include a base layer, a first transistor of a first color pixel emitting a first color of light that may be disposed over the base layer and that may include a first electrode, a second transistor of a second color pixel emitting a second color of light different than the first color of light that may be disposed over the base layer and that may include a first electrode, a first horizontal bus line and a second horizontal bus line disposed over the base layer and insulated from each other, and a first vertical bus line and a second vertical bus line that transfer a first high voltage and a second high voltage, respectively, and that are insulated from each other and disposed in a layer different from a layer in which the first horizontal bus line and the second horizontal bus line are disposed. The first vertical bus line may be electrically connected to the first electrode of the first transistor through the first horizontal bus line, and the second vertical bus line may be electrically connected to the first electrode of the second transistor through the second horizontal bus line.

In an embodiment, the electronic device may further include a first high voltage line disposed between the base layer and the first transistor, a first insulating layer disposed between the first high voltage line and the first transistor, and a second insulating layer disposed between the first transistor and the first horizontal bus line. The first horizontal bus line may be electrically connected to the first electrode of the first transistor through a contact hole that penetrates the second insulating layer.

In an embodiment, the electronic device may further include a third insulating layer disposed between the first horizontal bus line and the first vertical bus line, and the first vertical bus line may be electrically connected to the first horizontal bus line through a contact hole that penetrates the third insulating layer.

In an embodiment, the first horizontal bus line may be electrically connected to the first high voltage line through a contact hole that penetrates the first insulating layer and the second insulating layer.

In an embodiment, the electronic device may further include a first high voltage line that may be disposed between the base layer and the first transistor and that overlaps the first transistor, a first insulating layer disposed between the first high voltage line and the first transistor, a second insulating layer disposed between the first transistor and the first horizontal bus line, a third insulating layer disposed on the first horizontal bus line, and an intermediate insulating layer disposed between the third insulating layer and the first vertical bus line. The first vertical bus line may be electrically connected to the first horizontal bus line through a contact hole that penetrates the intermediate insulating layer and the third insulating layer, and the first horizontal bus line may be electrically connected to the first electrode of the first transistor through a contact hole that penetrates the second insulating layer.

In an embodiment, the second vertical bus line may be electrically connected to the second horizontal bus line through a contact hole that penetrates the intermediate insulating layer.

In an embodiment, the electronic device may further include a connecting line that may be disposed on the second insulating layer and that overlaps the second horizontal bus line. The second horizontal bus line may be electrically connected to the connecting line through a contact hole that penetrates the third insulating layer, and the connecting line may be electrically connected to the first electrode of the second transistor through a contact hole that penetrates the second insulating layer.

In an embodiment, the first horizontal bus line and the second horizontal bus line may extend in a first direction and may be spaced apart from each other in a second direction different from the first direction. The first vertical bus line and the second vertical bus line may extend in the second direction and may be spaced apart from each other in the first direction.

In an embodiment, each of the first horizontal bus line and the second horizontal bus line may extend in a first direction. At least a portion of the first horizontal bus line and at least a portion of the second horizontal bus line may be disposed to overlap each other when viewed from above a plane. The first vertical bus line and the second vertical bus line may extend in a second direction different from the first direction and may be spaced apart from each other in the first direction.

In an embodiment, the first high voltage and the second high voltage may have different voltage levels.

### BRIEF DESCRIPTION OF THE DRAWINGS

The above and other embodiments of the present disclosure will become apparent by describing in detail examples thereof with reference to the accompanying drawings.

FIG. 1 is a perspective view diagram of an electronic device according to an embodiment of the present disclosure.

FIG. 2 is an exploded perspective view diagram of an electronic device according to an embodiment of the present disclosure.

FIGS. 3A, 3B, and 3C illustrate circuit diagrams of a first color pixel, a second color pixel, and a third color pixel, respectively, according to an embodiment of the present disclosure.

FIG. 4 is a graphical diagram depicting voltage-current characteristics of first transistors of the first color pixel, the second color pixel, and the third color pixel according to an embodiment of the present disclosure.

FIG. 5 is a layout diagram illustrating a first driver circuit, a second driver circuit, a third driver circuit, and a fourth driver circuit that provide voltages to a display panel according to an embodiment of the present disclosure.

FIG. 6 is an enlarged view schematic diagram illustrating an area of the display panel illustrated in FIG. 5

FIG. 7 is a plan view diagram of a display panel according to an embodiment of the present disclosure.

FIG. 8 is a sectional side view diagram of a display panel according to an embodiment of the present disclosure.

FIG. 9 is a plan view diagram of a display panel according to an embodiment of the present disclosure.

FIG. 10 is a sectional side view diagram of a display panel according to an embodiment of the present disclosure.

### DETAILED DESCRIPTION

In the present disclosure, when a component an area, a layer, a part, or the like is referred to as being “on”, “connected to” or “coupled to” another component, this means that the component may be directly on, connected to, or coupled to the other component or a third component may be present therebetween.

The same or like reference numerals may refer to substantially the same or like components. Additionally, in the drawings, the thicknesses, proportions, and dimensions of components may be exaggerated for effective description. As used herein, the term “and/or” includes all of one or more combinations defined by related components.

Terms such as first, second, and the like may be used to describe various components, but the components should not be limited by the terms. These and like terms may be used for distinguishing one component from other components without any particular sequential meaning. For example, without departing from the scope of the present disclosure, a first component may be referred to as a second component, and/or a second component may be referred to as a first component. The terms of a singular form may include plural forms unless otherwise specified.

In addition, terms such as “below”, “under”, “above”, and “over” may be used to describe a relationship between components illustrated in the drawings. These terms are relative concepts and, like other relative concepts, may be described based on directions illustrated in the drawings.

It shall be understood that terms such as “comprise”, “include”, and “have”, when used herein, specify the presence of stated features, numbers, steps, operations, components, parts, or combinations thereof, but do not preclude the presence or addition of one or more other features, numbers, steps, operations, components, parts, or combinations thereof.

Unless otherwise defined, all terms used herein, including technical or scientific terms, have the same meanings as generally understood by those skilled in the art to which the present disclosure pertains. Such terms as those defined in a generally used dictionary are to be interpreted as having meanings equal to the contextual meanings in the relevant field of art, and are not to be interpreted as having idealized, theoretical or excessively formal meanings unless clearly defined as having such in the present application.

Hereinafter, embodiments of the present disclosure will be described with reference to the accompanying drawings.

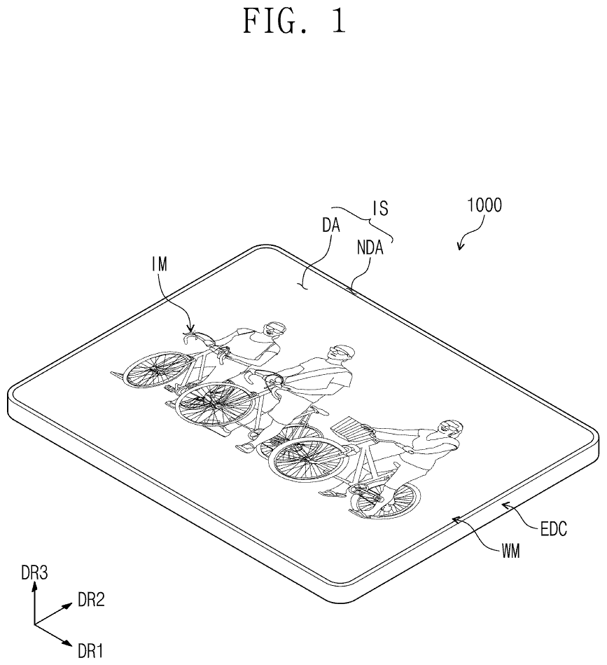

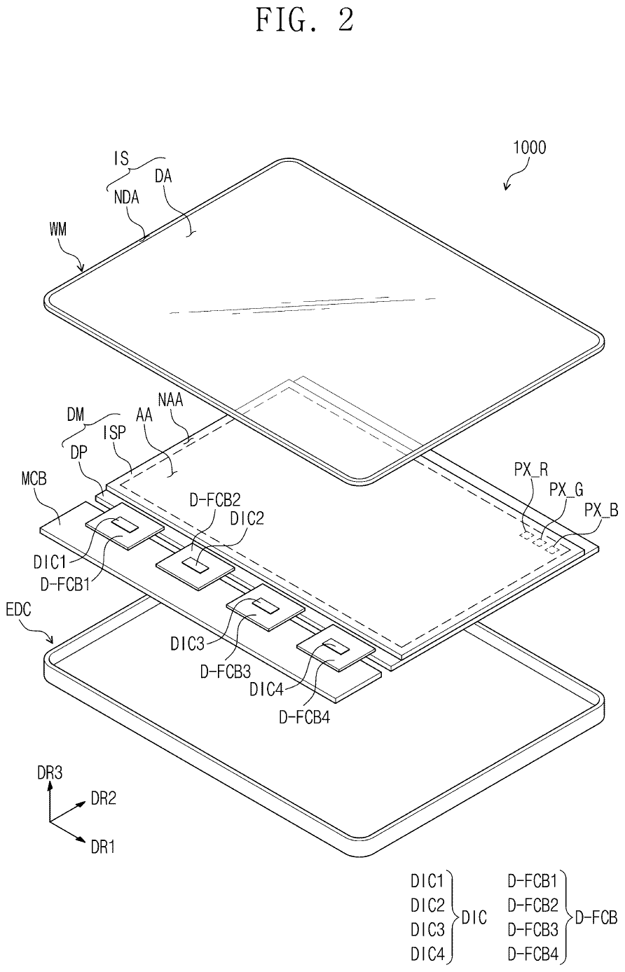

FIG. 1 illustrates an electronic device 1000 according to an embodiment of the present disclosure, and FIG. 2 illustrates an exploded perspective view of the electronic device 1000 according to an embodiment of the present disclosure.

Referring to FIGS. 1 and 2, the electronic device 1000 may be a device activated in response to an electrical signal. The electronic device 1000 according to the present disclosure may be a small and/or medium-sized electronic device such as a mobile phone, a tablet computer, a notebook computer, a car navigational device, a game machine, or the like, as well as a large electronic device such as a television, a monitor, or the like. These electronic devices are merely illustrative, and the electronic device 1000 may include other forms of electronic devices without departing from the scope and spirit of the present disclosure. The electronic device 1000 has a rectangular shape with long sides in a first direction DR1 and short sides in a second direction DR2 crossing the first direction DR1. However, without being limited thereto, the electronic device 1000 may have various shapes and dimensions. The electronic device 1000 may include an outer casing EDC that accommodates a window WM. The electronic device 1000 may display an image IM in a third direction DR3 on a display surface IS parallel to the first direction DR1 and the second direction DR2, without limitation thereto.

In this embodiment, for example, front surfaces or upper surfaces and rear surfaces or lower surfaces of members or components may be defined based on the direction in which the image IM is displayed. The front surfaces and the rear surfaces may be opposite each other in the third direction DR3, and the normal directions of the front surfaces and the rear surfaces may be parallel to the third direction DR3.

The separation distance between the front surface and the rear surface of the electronic device 1000 in the third direction DR3 may correspond to the thickness of the electronic device 1000 in the third direction DR3. Moreover, the directions indicated by the first through third directions DR1, DR2, and DR3 may be relative concepts and may be changed to other directions and/or coordinate systems.

The electronic device 1000 may sense an external input applied from the outside. The external input may include various forms of inputs provided from outside the electronic device 1000. The electronic device 1000, according to an embodiment of the present disclosure, may sense a user's external input applied from the outside. The user's external input may be one of various forms of external inputs, such as by proximity or position of a part of the user's body, light, heat, gaze, and/or pressure, or a combination thereof. In addition, the electronic device 1000 may sense the user's external input applied to the side surface or the rear surface of the electronic device 1000 depending on the structure of the electronic device 1000, and is not limited thereto. For example, in an embodiment of the present disclosure, the external input may include an input by an input device (e.g., a stylus pen, an active pen, a touch pen, an electronic pen, an e-pen, or the like).

The display surface IS of the electronic device 1000 may be divided into a display area DA and a non-display area NDA. The display area DA may be an area on which the image IM is displayed. The user visually recognizes the image IM through the display area DA. In this embodiment, the display area DA is illustrated in a rounded rectangular shape. However, this is illustrative, and the display area DA may have various shapes and is not limited thereto.

The non-display area NDA may be adjacent to the display area DA. The non-display area NDA may have a certain color. The non-display area NDA may surround the display area DA. Accordingly; the shape of the display area DA may be substantially defined by the non-display area NDA. However, this is illustrative, and the non-display area NDA may be disposed adjacent to only one side or fewer than all sides of the display area DA, or may be omitted. The electronic device 1000 of the present disclosure may include various modifications to realize other embodiments and is not limited to the example illustrated in FIG. 1.

As illustrated in FIG. 2, the electronic device 1000 may include a display module DM with the window WM disposed on the display module DM. The display module DM may include a display panel DP and an input sensing layer ISP.

The display panel DP according to an embodiment of the present disclosure may be an emissive display panel. For example, the display panel DP may be an organic light-emitting display panel, an inorganic light-emitting display panel, or a quantum-dot light-emitting display panel. An emissive layer of the organic light-emitting display panel may include an organic luminescent material. An emissive layer of the inorganic light-emitting display panel may include an inorganic luminescent material. An emissive layer of the quantum-dot light-emitting display panel may include quantum dots and quantum rods. Hereinafter, an example in which the display panel DP may be an organic light-emitting display panel may be described, without limitation thereto.

The display panel DP may output the image IM, and the output image IM may be displayed through the display surface IS. A plurality of pixels may be disposed in the display panel DP. The plurality of pixels may include a first color pixel PX_R, a second color pixel PX_G, and a third color pixel PX_B. In an embodiment, the first color pixel PX_R, the second color pixel PX_G, and the third color pixel PX_B may emit light of different colors. For example, the first color pixel PX_R, the second color pixel PX_G, and the third color pixel PX_B may emit red light, green light, and blue light, respectively.

The input sensing layer ISP may be disposed on the display panel DP and may sense an external input. The input sensing layer ISP may be directly disposed on the display panel DP, without limitation thereto. For example, according to an embodiment of the present disclosure, the input sensing layer ISP may be formed on the display panel DP by a continuous process. That is, when the input sensing layer ISP may be directly disposed on the display panel DP, an inner adhesive film is not disposed between the input sensing layer ISP and the display panel DP. However, without being limited thereto, an inner adhesive film may be disposed between the input sensing layer ISP and the display panel DP. In this case, the input sensing layer ISP need not be manufactured together with the display panel DP by a continuous process, and may, for example, be manufactured separately from the display panel DP and then fixed to the upper surface of the display panel DP by the inner adhesive film.

The window WM may be formed of a transparent material through which the image IM may be output. For example, the window WM may be formed of glass, sapphire, plastic, or the like. Although the window WM is illustrated as a single layer, the window WM is not limited thereto and may, for example, include a plurality of layers.

Moreover, the non-display area NDA of the electronic device 1000 described above may be substantially provided as an area where a material having a certain color may be printed on a partial area of the window WM. In an embodiment of the present disclosure, the window WM may include a light blocking pattern for defining the non-display area NDA. The light blocking pattern may be a colored organic film and may be formed, for example, by coating. Alternatively, the non-display area NDA may be illuminated by other means such as in a monotonic color to frame the display area and/or suit ambient lighting conditions.

The window WM may be coupled to the display module DM through an adhesive film. In an embodiment of the present disclosure, the adhesive film may include an optically clear adhesive (OCA) film. However, without being limited thereto, the adhesive film may include a conventional adhesive or sticky substance. For example, the adhesive film may include an optically clear resin (OCR) or a pressure sensitive adhesive (PSA) film.

An anti-reflective layer may also be disposed between the window WM and the display module DM. The anti-reflective layer may decrease the reflectance of external light incident from above the window WM under various conditions. The anti-reflective layer according to an embodiment of the present disclosure may include a phase retarder and/or a polarizer.

The display module DM may display the image IM in response to an electrical signal and may transmit/receive information about an external input. The display module DM may include an effective area AA and an ineffective area NAA defined therein. The effective area AA may be defined as an area that outputs the image IM provided by the display module DM. The effective area AA may alternately or additionally be defined as an area where the input sensing layer ISP senses an external input applied from the outside.

The ineffective area NAA may be adjacent to the effective area AA. For example, the ineffective area NAA may surround the effective area AA. However, this is illustrative, and the ineffective area NAA may be defined in various shapes and is not limited thereto. According to an embodiment, the effective area AA of the display module DM may correspond to at least a portion of the display area DA.

The electronic device 1000 may further include a main circuit board MCB, flexible circuit films D-FCB physically connected between the main circuit board MCB and the display panel DP, and driver circuits DIC disposed on the flexible circuit films D-FCB, without limitation thereto. The main circuit board MCB may be electrically connected to the display panel DP through the flexible circuit films D-FCB. The flexible circuit films D-FCB may be connected to the display panel DP to electrically connect the display panel DP and the main circuit board MCB. The main circuit board MCB may further include a plurality of elements. Each of the plurality of elements may include a circuit for driving the display panel DP. The driver circuits DIC may be mounted on and electrically connected to the flexible circuit films D-FCB.

In an embodiment of the present disclosure, the flexible circuit films D-FCB may include a first flexible circuit film D-FCB1, a second flexible circuit film D-FCB2, a third flexible circuit film D-FCB3, and a fourth flexible circuit film D-FCB4. The driver circuits DIC may include a first driver circuit DIC1 electrically connected to the first flexible circuit film D-FCB1, a second driver circuit DIC2 electrically connected to the second flexible circuit film D-FCB2, a third driver circuit DIC3 electrically connected to the third flexible circuit film D-FCB3, and a fourth driver circuit DIC4 electrically connected to the fourth flexible circuit film D-FCB4. The first through fourth flexible circuit films D-FCB1, D-FCB2, D-FCB3, and D-FCB4 may be spaced apart from each other in the first direction DR1 and may be connected to the display panel DP to electrically connect the display panel DP to the main circuit board MCB. The first driver circuit DIC1 may be mounted on the first flexible circuit film D-FCB1. The second driver circuit DIC2 may be mounted on the second flexible circuit film D-FCB2. The third driver circuit DIC3 may be mounted on the third flexible circuit film D-FCB3. The fourth driver circuit DIC4 may be mounted on the fourth flexible circuit film D-FCB4. However, embodiments of the present disclosure are not limited thereto. For example, the display panel DP may be electrically connected to the main circuit board MCB through one flexible circuit film, and one or more driver circuits may be mounted on the one flexible circuit film. Alternatively, the display panel DP may be electrically connected to the main circuit board MCB through two or more flexible circuit films, and driver circuits may be mounted on the flexible circuit films, respectively.

Although FIG. 2 illustrates a structure in which the first through fourth driver circuits DIC1, DIC2, DIC3, and DIC4 are mounted on the first through fourth flexible circuit films D-FCB1, D-FCB2, D-FCB3, and D-FCB4, respectively, the present disclosure is not limited thereto. For example, the first through fourth driver circuits DIC1, DIC2, DIC3, and DIC4 may be directly mounted on the display panel DP. In this case, the portion of the display panel DP on which the first through fourth driver circuits DIC1, DIC2, DIC3, and DIC4 are mounted may be bent and may be disposed on the rear surface of the display module DM, without limitation thereto. Alternatively, for example, the first through fourth driver circuits DIC1, DIC2, DIC3, and DIC4 may be directly mounted on the main circuit board MCB.

The input sensing layer ISP may be electrically connected to the main circuit board MCB through the flexible circuit films D-FCB. However, embodiments of the present disclosure are not limited thereto. For example, the display module DM may further include a separate flexible circuit film for electrically connecting the input sensing layer ISP to the main circuit board MCB.

The outer casing EDC of the electronic device 1000 may further accommodate the display module DM. The outer casing EDC may be coupled to the window WM to define the exterior of the electronic device 1000. The outer casing EDC protects components accommodated in the outer casing EDC, by absorbing impact applied from the outside and preventing infiltration of foreign matter/moisture into the display module DM. Moreover, in an embodiment of the present disclosure, the outer casing EDC may be provided in a form in which a plurality of receiving members are coupled.

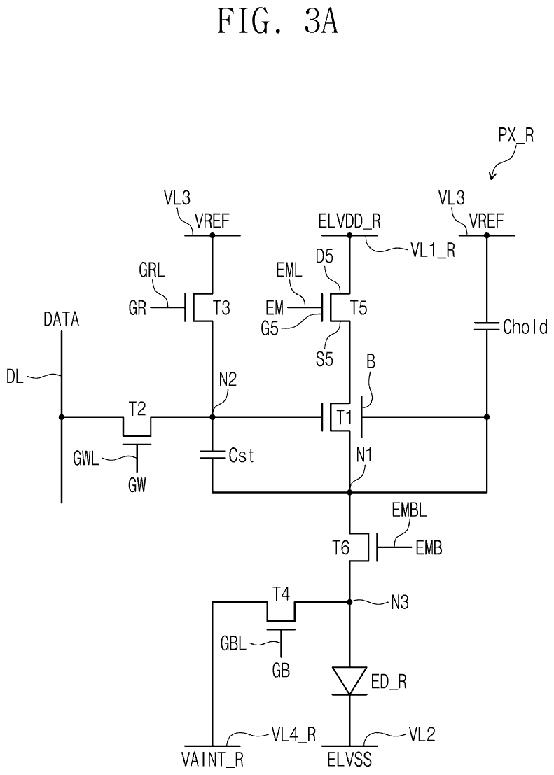

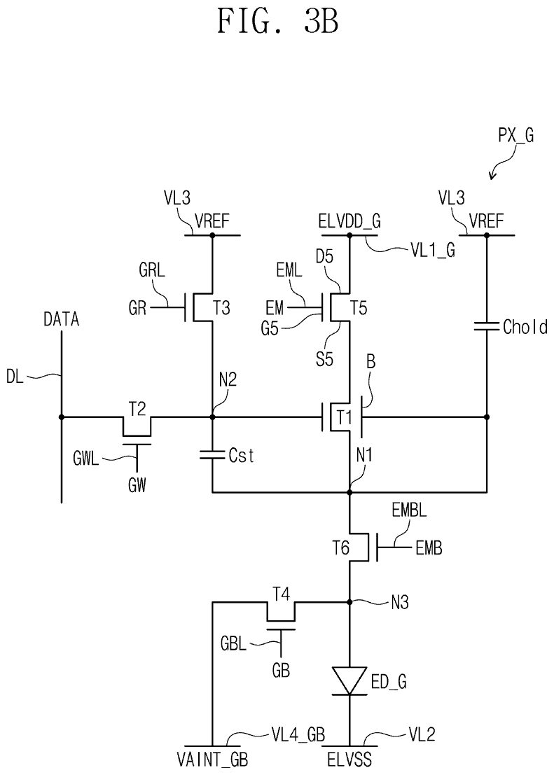

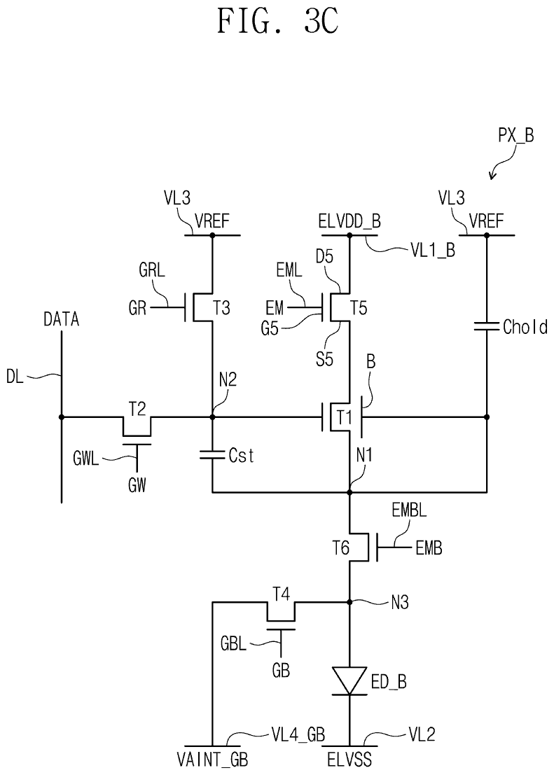

FIGS. 3A, 3B, and 3C illustrate the first color pixel PX_R, the second color pixel PX_G, and the third color pixel PX_B, respectively, according to an embodiment of the present disclosure.

Referring to FIG. 3A, the first color pixel PX_R may include first through sixth transistors T1, T2, T3, T4, T5, and T6, a first capacitor Cst, a second capacitor Chold, and a first light-emitting element ED_R, which may be configured to emit red colored light. Each of the first through sixth transistors T1-T6 may be an N-type transistor having an oxide semiconductor as a semiconductor layer. However, the present disclosure is not limited thereto. For example, each of the first through sixth transistors T1-T6 may be a P-type transistor having a low-temperature polycrystalline silicon (LTPS) semiconductor layer. In an embodiment, at least one of the first through sixth transistors T1-T6 may be an N-type transistor, and the remaining transistors may be P-type transistors. In addition, the circuit configuration of the first color pixel PX_R according to the present disclosure is not limited to that illustrated in FIG. 3A. The circuit configuration of the first color pixel PX_R illustrated in FIG. 3A is just one example, and various changes and modifications may be made to the circuit configuration based on the present disclosure.

Moreover, although illustrative embodiments may be shown and described where the high voltage lines connected to the light-emitting element anodes and voltage levels thereof are different for pixels emitting different colors of light, it shall be understood that like changes may be applied to the low voltage lines connected to the light-emitting element cathodes and voltage levels thereof in addition to and/or instead of the high voltage lines and/or voltage levels to achieve optimized voltage differences or current flows across the different colors of light-emitting elements in accordance with the present disclosure. For example, the low voltage line VL2 may include a first low voltage line VL2_R for first light-emitting elements configured to emit red light, a second low voltage line VL2_G for second light-emitting elements configured to emit green light, and a third low voltage line VL2_B for third light-emitting elements configured to emit blue light.

Referring to FIG. 3A, scan lines GWL, GRL, and GBL transfer scan signals GW, GR, and GB, and emission lines EML and EMBL transfer emission signals EM and EMB. A data line DL transfers a data signal DATA. The data signal DATA may have a voltage level corresponding to a pixel luminance of an image to be displayed on the first light-emitting element ED_R.

A first high voltage line VL1_R, a low voltage line VL2, a reference voltage line VL3, and a first initialization voltage line VL4_R may transfer a first high voltage ELVDD_R, a low voltage ELVSS, a reference voltage VREF, and a first initialization voltage VAINT_R, respectively, to the first color pixel PX_R.

The first transistor T1 may include a first electrode, a second electrode connected to a first node N1, a gate electrode connected to a second node N2, and a lower gate electrode B connected to the first node N1. The second electrode and the lower gate electrode B of the first transistor T1 may be commonly connected to the first node N1.

The second transistor T2 may be connected between the data line DL and the second node N2 and may include a gate electrode connected to the scan line GWL.

The third transistor T3 may be connected between the reference voltage line VL3 and the second node N2 and may include a gate electrode connected to the scan line GRL.

The fourth transistor T4 may include a first electrode connected to a third node N3, a second electrode connected to the first initialization voltage line VL4_R, and a gate electrode connected to the scan line GBL.

The fifth transistor T5 may include a first electrode D5 connected to the first high voltage line VL1_R, a second electrode S5 connected to the first electrode of the first transistor T1, and a gate electrode G5 connected to the emission line EML.

The sixth transistor T6 may be connected between the first node N1 and the third node N3 and may include a gate electrode connected to the emission line EMBL.

The first capacitor Cst may be connected between the first node N1 and the second node N2. The second capacitor Chold may be connected between the reference voltage line VL3 and the first node N1.

The first light-emitting element ED_R may be connected between the third node N3 and the low voltage line VL2.

A current corresponding to the data signal DATA transferred by the data line DL may be supplied to the first light-emitting element ED_R depending on a switching operation in which the first through sixth transistors T1-T6 are turned on/off in response to the scan signals GW, GR, and GB and the emission signals EM and EMB. As a result, the first light-emitting element ED_R may emit light having a chrominance corresponding to the color of the light-emitting element and a luminance corresponding to the data signal DATA.

Similarly to the first color pixel PX_R illustrated in FIG. 3A, the second color pixel PX_G illustrated in FIG. 3B and the third color pixel PX_B illustrated in FIG. 3C include first through sixth transistors T1, T2, T3, T4, T5, and T6, a first capacitor Cst, and a second capacitor Chold. Therefore, substantially the same or like components may be assigned substantially the same or like reference numerals, and substantially repetitive descriptions thereof may be omitted.

The fifth transistor T5 of the second color pixel PX_G illustrated in FIG. 3B may be connected between a second high voltage line VL1_G and a first electrode of the first transistor T1. The fourth transistor T4 of the second color pixel PX_G may be connected between a second initialization voltage line VL4_GB and a third node N3. The second high voltage line VL1_G and the second initialization voltage line VL4_GB transfer a second high voltage ELVDD_G and a second initialization voltage VAINT_GB, respectively. The second color pixel PX_G illustrated in FIG. 3B may include a second light-emitting element ED_G. which may be configured to emit green colored light.

The fifth transistor T5 of the third color pixel PX_B illustrated in FIG. 3C may be connected between a third high voltage line VL1_B and a first electrode of the first transistor T1. The fourth transistor T4 of the third color pixel PX_B may be connected between a second initialization voltage line VL4_GB and a third node N3. The third high voltage line VL1_B and the second initialization voltage line VL4_GB transfer a third high voltage ELVDD_B and the second initialization voltage VAINT_GB, respectively. The third color pixel PX_B illustrated in FIG. 3C may include a third light-emitting element ED_B, which may be configured to emit blue colored light.

In an embodiment, the first light-emitting element ED_R, the second light-emitting element ED_G, and the third light-emitting element ED_B may emit light of different colors. For example, the first light-emitting element ED_R, the second light-emitting element ED_G, and the third light-emitting element ED_B may emit red light, green light, and blue light, respectively.

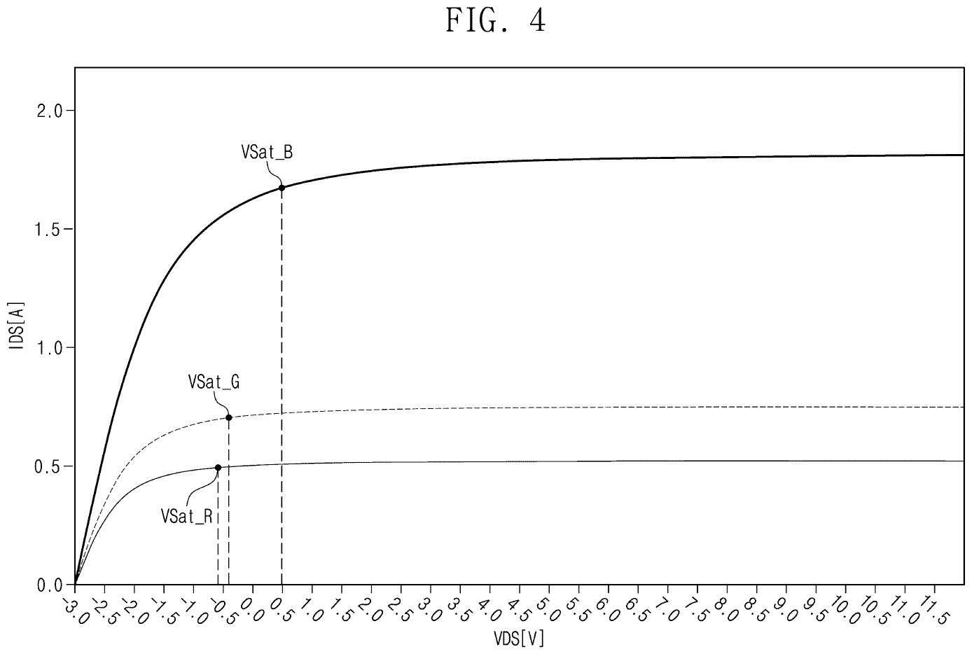

FIG. 4 illustrates voltage-current characteristics of the first transistors T1 of the first color pixel PX_R, the second color pixel PX_G, and the third color pixel PX_B.

In FIG. 4, the horizontal axis represents the voltage VDS between the first electrode and the second electrode of each of the first transistors T1, and the vertical axis represents the current IDS between the first electrode and the second electrode of the first transistor T1.

Referring to FIGS. 3A, 3B, 3C, and 4, when the voltage VDS between the first electrode and the second electrode of the first transistor T1 increases from −3.0 V, the current IDS increases. When the voltage VDS between the first electrode and the second electrode of the first transistor T1 reaches a specific level, the current IDS no longer increases and may be maintained at a constant level. The voltage VDS at which the current IDS is maintained at a substantially constant level may be referred to as a saturation voltage. As shown in the embodiment of FIG. 4, the saturation voltages VSat_R, VSat_G, and VSat_B of the first color pixel PX_R, the second color pixel PX_G, and the third color pixel PX_B, respectively, may be different from each other.

Accordingly, the first high voltage ELVDD_R, the second high voltage ELVDD_G, and the third high voltage ELVDD_B provided to the first electrodes D5 of the fifth transistors T5 of the first color pixel PX_R, the second color pixel PX_G, and the third color pixel PX_B, may be set to different voltage levels.

In an embodiment, the first color pixel PX_R is connected to receive the first high voltage ELVDD_R and the first initialization voltage VAINT_R that correspond to red light. The second color pixel PX_G is connected to receive the second high voltage ELVDD_G that corresponds to green light and the second initialization voltage VAINT_GB that corresponds to green and blue light. The third color pixel PX_B is connected to receive the third high voltage ELVDD_B that corresponds to blue light and the second initialization voltage VAINT_GB that corresponds to green and blue light.

By setting the first high voltage ELVDD_R, the second high voltage ELVDD_G, and the third high voltage ELVDD_B to different optimized voltage levels, the power consumed by the first color pixel PX_R, the second color pixel PX_G, and the third color pixel PX_B may be minimized. Accordingly, the power consumption of the electronic device 1000, such as shown in FIG. 1, may be minimized.

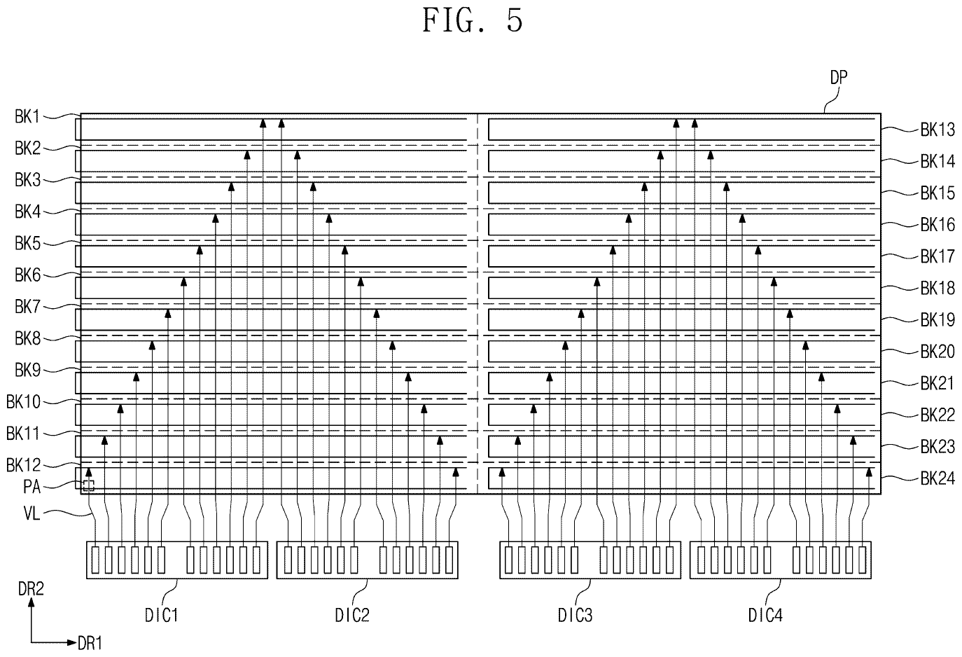

FIG. 5 illustrates a first driver circuit DIC1, a second driver circuit DIC2, a third driver circuit DIC3, and a fourth driver circuit DIC4 that provide voltages to the display panel DP.

Referring to FIG. 5, the display panel DP may include first through twenty-fourth blocks BK1-BK24.

Although FIG. 5 illustrates that the display panel DP may be divided into two blocks in the first direction DR1 and may be divided into twelve blocks in the second direction DR2, the present disclosure is not limited thereto. For example, the display panel DP may be divided into two or more blocks, and the arrangement and size of the blocks may be changed in various ways.

In an embodiment, the first driver circuit DIC1 and the second driver circuit DIC2 may provide voltages to the first through twelfth blocks BK1-BK12 through voltage lines VL, and the third driver circuit DIC3 and the fourth driver circuit DIC4 may provide voltages to the thirteenth through twenty-fourth blocks BK13-BK24 through voltage lines VL.

The voltage lines VL may include the first high voltage line VL1_R, the second high voltage line VL1_G, the third high voltage line VL1_B, the low voltage line VL2, the reference voltage line VL3, the first initialization voltage line VL4_R, and the second initialization voltage line VL4_GB as illustrated in FIGS. 3A to 3C.

An image displayed on the display panel DP may include not only a still image such as text or a picture, but also a moving image such as a movie. In addition, a still image and a moving image may be simultaneously displayed on one display panel DP. A specific image may have a high luminance on some of the first through twenty-fourth blocks BK1-BK24 of the display panel DP and may have a low luminance on the other blocks.

Depending on the characteristics of the image displayed on the display panel DP, the first high voltage ELVDD_R, the second high voltage ELVDD_G, the third high voltage ELVDD_B, the first initialization voltage VAINT_R, and the second initialization voltage VAINT_GB provided to each of the first through twenty-fourth blocks BK1-BK24 may be set to optimized voltage levels. Accordingly, the power consumed by the display panel DP may be further minimized.

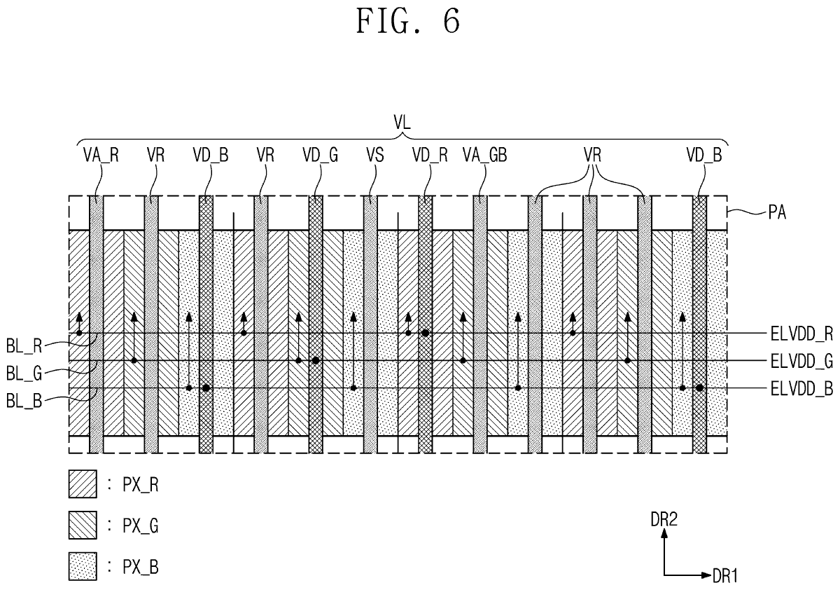

FIG. 6 illustrates an area PA of the display panel DP illustrated in FIG. 5.

Referring to FIGS. 3A and 6, the first color pixel PX_R, the second color pixel PX_G, and the third color pixel PX_B may be alternately arranged such as in a sequential order in the first direction DR1.

The voltage lines VL may include vertical bus lines VD_R, VD_G, VD_B, VS, VR, VA_R, and VA_GB. The vertical bus lines VD_R, VD_G, VD_B, VS, VR, VA_R, and VA_GB may extend in the second direction DR2 and be spaced apart from each other in the first direction DR1. The vertical bus lines VD_R for supplying the first high voltage ELVDD_R through the horizontal bus line BL_R to the pixel line VL1_R, VD_G for supplying the second high voltage ELVDD_G through the horizontal bus line BL_G to the pixel line VL1_G, VD_B for supplying the third high voltage ELVDD_B through the horizontal bus line BL_B to the pixel line VL1_B, VS for supplying the low voltage ELVSS to the pixel line VL2, VR for supplying the reference voltage VREF to the pixel line VL3, VA_R for supplying the first initialization voltage VAINT_R to the pixel line VL4_R, and VA_GB for supplying the second initialization voltage VAINT_GB to the pixel line VL4_GB may be insulated from each other.

Thus, the vertical bus lines VD_R, VD_G, VD_B, VS, VR, VA_R, and VA_GB transfer the first high voltage ELVDD_R, the second high voltage ELVDD_G, the third high voltage ELVDD_B, the low voltage ELVSS, the reference voltage VREF, the first initialization voltage VAINT_R, and the second initialization voltage VAINT_GB, respectively.

A first horizontal bus line BL_R, a second horizontal bus line BL_G, and a third horizontal bus line BL_B may be further disposed in the area PA of the display panel DP. The first horizontal bus line BL_R, the second horizontal bus line BL_G, and the third horizontal bus line BL_B extend in the first direction DR1 and are spaced apart from each other in the second direction DR2. The first horizontal bus line BL_R, the second horizontal bus line BL_G, and the third horizontal bus line BL_B are insulated from each other.

In this embodiment, the term “horizontal” means a direction parallel to the first direction DR1, and the term “vertical” means a direction parallel to the second direction DR2. However, the arrangement directions of the vertical bus lines VD_R, VD_G, VD_B, VS, VR, VA_R, and VA_GB and the first through third horizontal bus lines BL_R, BL_G, and BL_B are not limited thereto. For example, the vertical bus lines VD_R, VD_G, and VD_B and the first through third horizontal bus lines BL_R, BL_G, and BL_B may be diversely arranged in a shape in which at least portions thereof overlap each other or in a shape in which at least portions thereof cross each other.

According to the general characteristics of the first light-emitting element ED_R, the second light-emitting element ED_G, and the third light-emitting element ED_B, the voltage drop or the IR drop of the third light-emitting element ED_B may be greater than the voltage drops of the first light-emitting element ED_R and the second light-emitting element ED_G. Accordingly, it may be appropriate that the number of vertical bus lines D_B per unit area be greater than the number of vertical bus lines VD_R per unit area and the number of vertical bus lines VD_G per unit area.

One pixel unit may include a first color pixel PX_R, a second color pixel PX_G, and a third color pixel PX_B. For example, four pixel units may include four first color pixels PX_R, four second color pixels PX_G, and four third color pixels PX_B.

In the embodiment illustrated in FIG. 6, for four pixel units (e.g., twelve color pixels), the number of vertical bus lines VD_B may be 2, the number of vertical bus lines VD_R may be 1, the number of vertical bus lines VD_G may be 1. However, the present disclosure is not limited thereto. For example, the numbers of vertical bus lines VD_R, VD_G, and VD_B may be changed in various ways depending on the characteristics of the first light-emitting element ED_R, the second light-emitting element ED_G, and the third light-emitting element ED_B.

The first horizontal bus line BL_R, the second horizontal bus line BL_G, and the third horizontal bus line BL_B may be electrically connected to the vertical bus lines VD_R, VD_G, and VD_B, respectively.

The first horizontal bus line BL_R, the second horizontal bus line BL_G, and the third horizontal bus line BL_B may transfer the first high voltage ELVDD_R, the second high voltage ELVDD_G, and the third high voltage ELVDD_B transferred by the vertical bus lines VD_R, VD_G, and VD_B to the first color pixel PX_R, the second color pixel PX_G, and the third color pixel PX_B, respectively.

The first high voltage ELVDD_R transferred through the first horizontal bus line BL_R may be provided to the first color pixels PX_R. The second high voltage ELVDD_G transferred through the second horizontal bus line BL_G may be provided to the second color pixels PX_G. The third high voltage ELVDD_B transferred through the third horizontal bus line BL_B may be provided to the third color pixels PX_B.

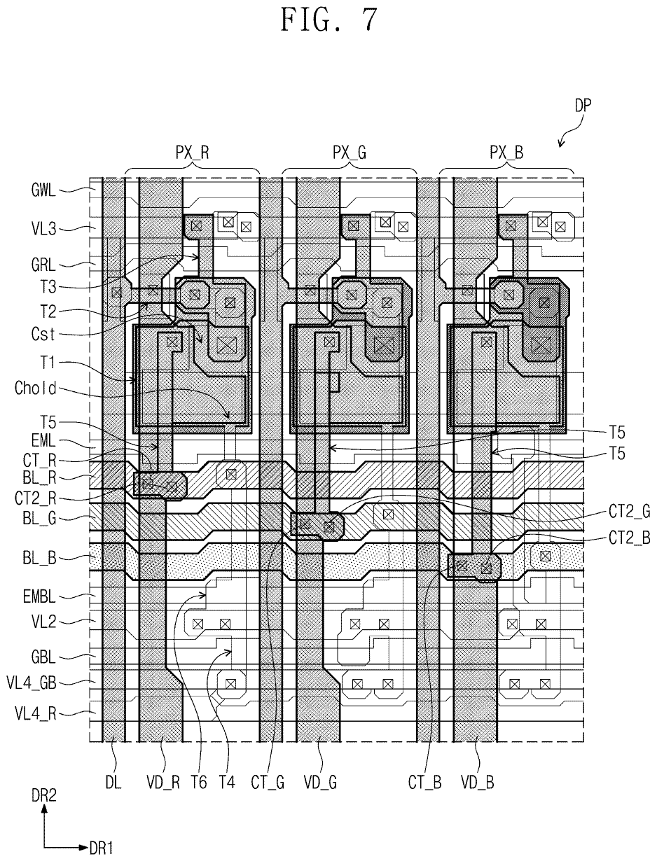

FIG. 7 illustrates a display panel DP according to an embodiment of the present disclosure.

Although FIG. 7 illustrates that the first color pixel PX_R, the second color pixel PX_G, and the third color pixel PX_B may be sequentially arranged in the first direction DR1, the present disclosure is not limited thereto. For example, the arrangement order of the first color pixel PX_R, the second color pixel PX_G, and the third color pixel PX_B may be changed in various ways. In addition, the shape and size of the area where each of the first color pixel PX_R, the second color pixel PX_G, and the third color pixel PX_B is disposed may be changed in various ways.

In this embodiment, the first color pixel PX_R, the second color pixel PX_G, and the third color pixel PX_B may include substantially similar components. Therefore, the first color pixel PX_R will hereinafter be described, and substantially repetitive descriptions of the second color pixel PX_G and the third color pixel PX_B may be omitted.

Referring to FIG. 7, the first color pixel PX_R may include the first through sixth transistors T1-T6, the first capacitor Cst, and the second capacitor Chold.

The scan lines GWL, GRL, and GBL, the emission lines EML and EMBL, the first horizontal bus line BL_R, the second horizontal bus line BL_G, and the third horizontal bus line BL_B may each extend in the first direction DR1 and be spaced apart from each other in the second direction DR2.

The data line DL and the vertical bus lines VD_R, VD_G, and VD_B may each extend in the second direction DR2 and be spaced apart from each other in the first direction DR1.

The vertical bus line VD_R and the first horizontal bus line BL_R may be electrically connected through a first bus contact hole CT_R. In addition, the first horizontal bus line BL_R and the fifth transistor T5 of the first color pixel PX_R may be electrically connected through a contact hole CT2_R.

The vertical bus line VD_G and the second horizontal bus line BL_G may be electrically connected through a second bus contact hole CT_G. In addition, the second horizontal bus line BL_G and the fifth transistor T5 of the second color pixel PX_G may be electrically connected through a contact hole CT2_G.

The vertical bus line VD_B and the third horizontal bus line BL_B may be electrically connected through a third bus contact hole CT_B. In addition, the third horizontal bus line BL_B and the fifth transistor T5 of the third color pixel PX_B may be electrically connected through a contact hole CT2_B.

The vertical bus line VD_R and the fifth transistor T5 of the first color pixel PX_R may be electrically connected through the first bus contact hole CT_R and the contact hole CT2_R. Similarly, the vertical bus line VD_G and the fifth transistor T5 of the second color pixel PX_G may be electrically connected through the second bus contact hole CT_G and the contact hole CT2_G. Moreover, the vertical bus line VD_B and the fifth transistor T5 of the third color pixel PX_B may be electrically connected through the third bus contact hole CT_B and the contact hole CT2_B.

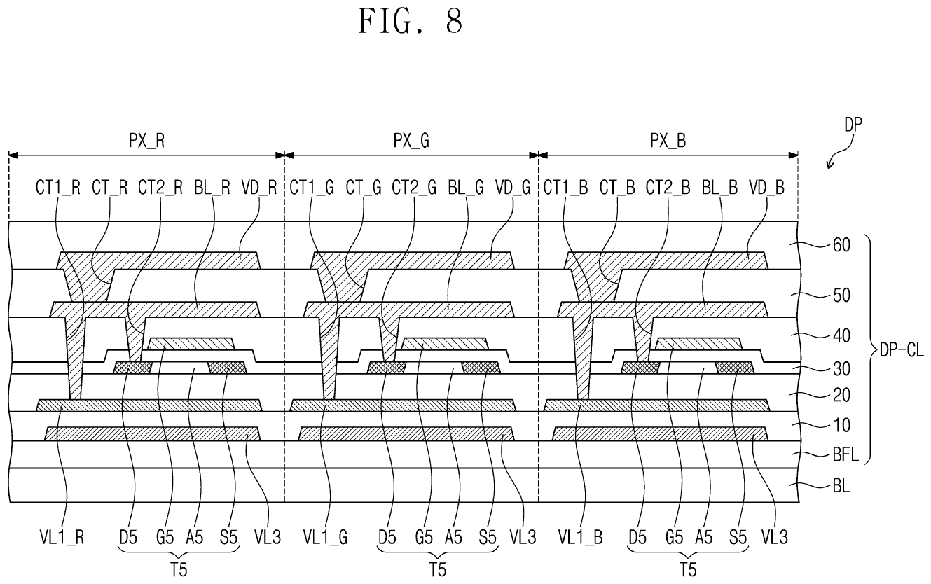

FIG. 8 illustrates a display panel DP according to an embodiment of the present disclosure.

FIG. 8 illustrates a cross-section of portions corresponding to the fifth transistors T5 of the first color pixel PX_R, the second color pixel PX_G, and the third color pixel PX_B. The other transistors T1, T2, T3, T4, and T6 constituting each of the first color pixel PX_R, the second color pixel PX_G, and the third color pixel PX_B may have substantially the same structure as the fifth transistors T5 illustrated in FIG. 8. Substantially duplicate description may be omitted. However, it shall be understood that this is merely illustrative, and the other transistors T1, T2, T3, T4, and T6 may have a structure or structures different from those of the fifth transistors T5, without limitation thereto.

Referring to FIG. 8, the display panel DP may include a base layer BL and a circuit element layer DP-CL disposed on the base layer BL. The display panel DP may include a display element layer and a thin film encapsulation layer that are disposed on the circuit element layer DP-CL. The first light-emitting element ED_R, the second light-emitting element ED_G, and the third light-emitting element ED_B may be disposed in the display element layer. The thin film encapsulation layer may be commonly disposed in the first color pixel PX_R, the second color pixel PX_G, and the third color pixel PX_B. The display panel DP may further include functional layers such as a refractive index control layer.

The circuit element layer DP-CL may include at least a plurality of insulating layers and a circuit element. Hereinafter, the insulating layers may include an organic layer and/or an inorganic layer.

An insulating layer, a semiconductor layer, and a conductive layer are formed through a process such as coating, deposition, or the like. Thereafter, the insulating layer, the semiconductor layer, and the conductive layer may be selectively subjected to patterning through a photolithography process and an etching process. A semiconductor pattern, a conductive pattern, and a signal line are formed through the above-described processes. Patterns disposed on substantially the same layer may be formed through substantially the same process.

The base layer BL may include a synthetic resin layer. The synthetic resin layer may include a thermosetting resin. In particular, the synthetic resin layer may be a polyimide-based resin layer, and the material thereof is not particularly limited. For example, the synthetic resin layer may include at least one of an acrylic resin, a methacrylic resin, a polyisoprene resin, a vinyl resin, an epoxy resin, a urethane-based resin, a cellulosic resin, a siloxane-based resin, a polyamide resin, and a perylene-based resin. In addition, the base layer BL may include a glass substrate, a metal substrate, and/or an organic/inorganic composite substrate.

At least one inorganic layer may be formed on the upper surface of the base layer BL. The inorganic layer may include at least one of aluminum oxide, titanium oxide, silicon oxide, silicon oxy nitride, zirconium oxide, and hafnium oxide. The inorganic layer may be formed of multiple layers. At least one of the multiple inorganic layers may constitute a buffer layer BFL.

The buffer layer BFL may be an inorganic layer. A first conductive layer may be disposed on the buffer layer BFL. The first conductive layer may be the reference voltage line VL3 for transferring the reference voltage VREF. Although FIG. 8 illustrates that the first conductive layer may be divided to correspond to the first color pixel PX_R, the second color pixel PX_G, and the third color pixel PX_B, the present disclosure is not limited thereto. For example, the first conductive layer may be commonly disposed in the first color pixel PX_R, the second color pixel PX_G, and the third color pixel PX_B.

A first insulating layer 10 may be disposed on the reference voltage line VL3. The first insulating layer 10 covers the reference voltage line VL3.

The first insulating layer 10 may be an inorganic layer and/or an organic layer and may have a single-layer structure or a multi-layer structure. The first insulating layer 10 may include at least one of aluminum oxide, titanium oxide, silicon oxide, silicon oxy nitride, zirconium oxide, and hafnium oxide. Not only the first insulating layer 10, but also insulating layers of the circuit element layer DP-CL, which may be described in greater detail below, may be inorganic layers and/or organic layers and may have a single layer structure or a multi-layer structure. The inorganic layers may include at least one of the aforementioned materials.

A second conductive layer may be disposed on the first insulating layer 10. The second conductive layer may include the first high voltage line VL1_R, the second high voltage line VL1_G, and the third high voltage line VL1_B. The first high voltage line VL1_R, the second high voltage line VL1_G, and the third high voltage line VL1_B may be disposed to overlap the first color pixel PX_R, the second color pixel PX_G, and the third color pixel PX_B, respectively.

A second insulating layer 20 may be disposed on the first high voltage line VL1_R, the second high voltage line VL1_G, and the third high voltage line VL1_B. The second insulating layer 20 covers the first high voltage line VL1_R, the second high voltage line VL1_G, and the third high voltage line VL1_B.

The fifth transistors T5 may be disposed on the second insulating layer 20. Each of the fifth transistors T5 may include a semiconductor pattern and a gate electrode G5. The semiconductor pattern may be disposed on the second insulating layer 20. The semiconductor pattern may include a source electrode S5, a drain electrode D5, and a channel area A5 that are distinguished from each other depending on the degree of conductivity.

A third insulating layer 30 may commonly overlap the first color pixel PX_R, the second color pixel PX_G, and the third color pixel PX_B and may cover the semiconductor patterns. The gate electrodes G5 may be disposed on the third insulating layer 30, without limitation thereto.

A fourth insulating layer 40 may be disposed on the third insulating layer 30. The fourth insulating layer 40 covers the gate electrodes G5.

The first horizontal bus line BL_R, the second horizontal bus line BL_G, and the third horizontal bus line BL_B are disposed on the fourth insulating layer 40. The first horizontal bus line BL_R may be connected to the first high voltage line VL1_R through a contact hole CT1_R that penetrates the second insulating layer 20, the third insulating layer 30, and the fourth insulating layer 40. The first horizontal bus line BL_R may be connected to the drain electrode D5 of the fifth transistor T5 within the first color pixel PX_R through the contact hole CT2_R that penetrates the third insulating layer 30 and the fourth insulating layer 40.

The second horizontal bus line BL_G may be connected to the second high voltage line VL1_G through a contact hole CT1_G that penetrates the second insulating layer 20, the third insulating layer 30, and the fourth insulating layer 40. The second horizontal bus line BL_G may be connected to the drain electrode D5 of the fifth transistor T5 within the second color pixel PX_G through the contact hole CT2_G that penetrates the third insulating layer 30 and the fourth insulating layer 40.

The third horizontal bus line BL_B may be connected to the third high voltage line VL1_B through a contact hole CT1_B that penetrates the second insulating layer 20, the third insulating layer 30, and the fourth insulating layer 40. The third horizontal bus line BL_B may be connected to the drain electrode D5 of the fifth transistor T5 within the third color pixel PX_B through the contact hole CT2_B that penetrates the third insulating layer 30 and the fourth insulating layer 40.

A fifth insulating layer 50 may be disposed on the fourth insulating layer 40. The fifth insulating layer 50 may cover the first horizontal bus line BL_R, the second horizontal bus line BL_G, and the third horizontal bus line BL_B, without limitation thereto.

The vertical bus lines VD_R, VD_G, and VD_B are disposed on the fifth insulating layer 50. The vertical bus line VD_R may be connected to the first horizontal bus line BL_R through the first bus contact hole CT_R that penetrates the fifth insulating layer 50. The vertical bus line VD_G may be connected to the second horizontal bus line BL_G through the second bus contact hole CT_G that penetrates the fifth insulating layer 50. The vertical bus line VD_B may be connected to the third horizontal bus line BL_B through the third bus contact hole CT_B that penetrates the fifth insulating layer 50.

A sixth insulating layer 60 may be disposed on the fifth insulating layer 50. The sixth insulating layer 60 may cover the vertical bus lines VD_R, VD_G, and VD_B, without limitation thereto.

The first high voltage ELVDD_R, the second high voltage ELVDD_G, and the third high voltage ELVDD_B transferred through the vertical bus lines VD_R, VD_G, and VD_B may be transferred to the fifth transistors T5 of the first color pixel PX_R, the second color pixel PX_G, and the third color pixel PX_B through the first horizontal bus line BL_R, the second horizontal bus line BL_G, and the third horizontal bus line BL_B. Depending on the characteristics of the first color pixel PX_R, the second color pixel PX_G, and the third color pixel PX_B, the first high voltage ELVDD_R, the second high voltage ELVDD_G, and the third high voltage ELVDD_B may be set to optimized voltage levels, and thus the power consumed by the display panel DP may be further minimized.

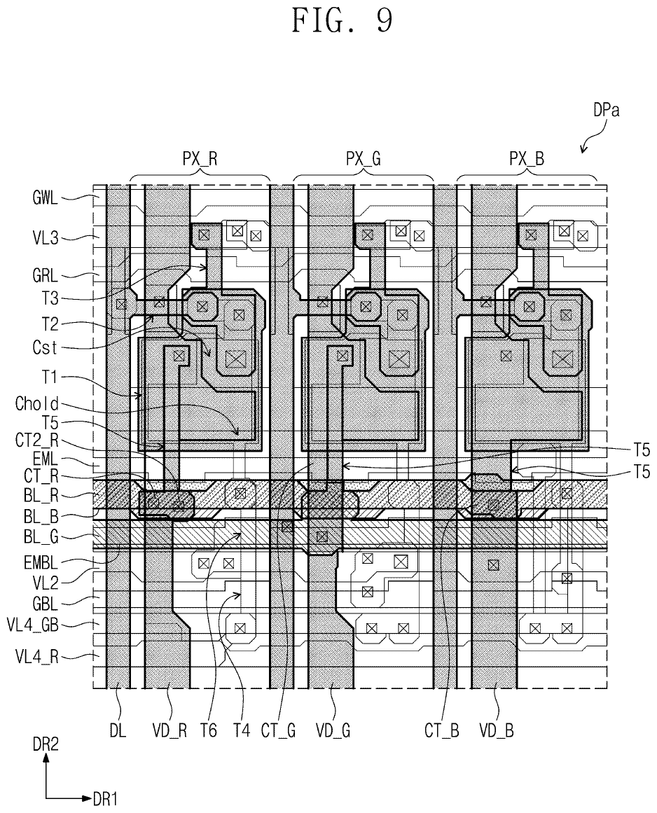

FIG. 9 illustrates a display panel DPa according to an embodiment of the present disclosure.

In FIG. 9, an area comparable to that of FIG. 7 is illustrated. Hereinafter, components substantially the same or like the components described with reference to FIG. 7 may be assigned substantially the same or like reference numerals, and substantially repetitive descriptions may be omitted.

Referring to FIG. 9, each of a first horizontal bus line BL_R, a second horizontal bus line BL_G, and a third horizontal bus line BL_B may extend in the first direction DR1. The first horizontal bus line BL_R and the second horizontal bus line BL_G may be disposed to overlap each other when viewed from the third direction DR3 or from above a plane. In an embodiment, the first horizontal bus line BL_R may be disposed above the second horizontal bus line BL_G. The first horizontal bus line BL_R and the third horizontal bus line BL_B are spaced apart from each other in the second direction DR2.

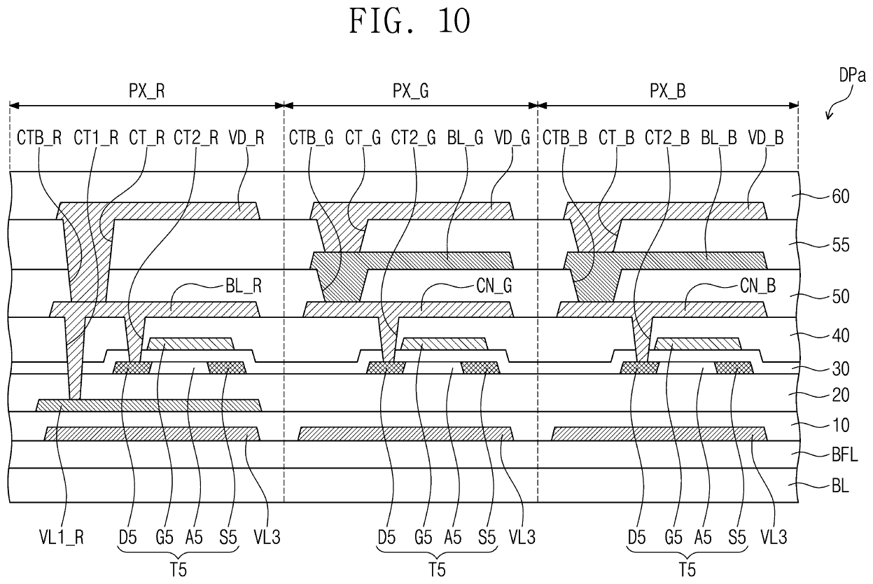

FIG. 10 illustrates a display panel DPa according to an embodiment of the present disclosure.

In FIG. 10, an area corresponding to FIG. 8 is illustrated. Hereinafter, components substantially the same or like the components described with reference to FIG. 8 may be assigned substantially the same or like reference numerals, and substantially repetitive descriptions may be omitted.

A second conductive layer disposed on a first insulating layer 10 may include a first high voltage line VL1_R.

The first horizontal bus line BL_R, a connecting line CN_G, and a connecting line CN_B are disposed on a fourth insulating layer 40. The first horizontal bus line BL_R may be connected to the first high voltage line VL1_R through a contact hole CT1_R that penetrates the second insulating layer 20, the third insulating layer 30, and the fourth insulating layer 40. The first horizontal bus line BL_R may be connected to a drain electrode D5 of a fifth transistor T5 within a first color pixel PX_R through a contact hole CT2_R that may penetrate the third insulating layer 30 and/or the fourth insulating layer 40. In an alternate embodiment, the lines disposed on the fourth insulating layer 40, including the first horizontal bus line BL_R and/or the connecting lines CN_G and CN_B, need not be disposed horizontally. For example, these lines may instead be disposed diagonally.

The connecting line CN_G may be connected to a drain electrode D5 of a fifth transistor T5 within a second color pixel PX_G through a contact hole CT2_G that may penetrate the third insulating layer 30 and/or the fourth insulating layer 40.

The connecting line CN_B may be connected to a drain electrode D5 of a fifth transistor T5 within a third color pixel PX_B through a contact hole CT2_G that may penetrate the third insulating layer 30 and/or the fourth insulating layer 40.

A fifth insulating layer 50 may be disposed on the fourth insulating layer 40. The fifth insulating layer 50 may cover the first horizontal bus line BL_R, the connecting line CN_G, and the connecting line CN_B.

The second horizontal bus line BL_G and the third horizontal bus line BL_B may be disposed on the fifth insulating layer 50.

The second horizontal bus line BL_G may be connected to the connecting line CN_G through a contact hole CTB_G that penetrates the fifth insulating layer 50. The third horizontal bus line BL_B may be connected to the connecting line CN_B through a contact hole CTB_B that penetrates the fifth insulating layer 50.

An intermediate insulating layer 55 may be disposed on the fifth insulating layer 50. The intermediate insulating layer 55 may cover the second horizontal bus line BL_G and the third horizontal bus line BL_B.

Vertical bus lines VD_R, VD_G, and VD_B may be disposed on the intermediate insulating layer 55. The vertical bus line VD_R may be connected to the first horizontal bus line BL_R through a first bus contact hole CT_R that penetrates the intermediate insulating layer 55 and the fifth insulating layer 50. The vertical bus line VD_G may be connected to the second horizontal bus line BL_G through a second bus contact hole CT_G that penetrates the intermediate insulating layer 55. The vertical bus line VD_B may be connected to the third horizontal bus line BL_B through a third bus contact hole CT_B that penetrates the intermediate insulating layer 55.

A first high voltage ELVDD_R supplied through the vertical bus line VD_R may be transferred to the first color pixels PX_R through the first horizontal bus line BL_R.

A second high voltage ELVDD_G supplied through the vertical bus line VD_G may be transferred to the fifth transistor T5 of the second color pixel PX_G through the second horizontal bus line BL_G and the connecting line CN_G.

A third high voltage ELVDD_B supplied through the vertical bus line VD_B may be transferred to the fifth transistor T5 of the third color pixel PX_B through the third horizontal bus line BL_B and the connecting line CN_B.

Based on the characteristics of the first color pixel PX_R, the second color pixel PX_G, and the third color pixel PX_B, the first high voltage ELVDD_R, the second high voltage ELVDD_G, and the third high voltage ELVDD_B may be set to optimized voltage levels, and thus the power consumed by the display panel DPa may be further minimized.

In addition, as illustrated in FIG. 9, the first horizontal bus line BL_R and the second horizontal bus line BL_G may be disposed to overlap each other when viewed from above the plane, and thus the lengths of the first color pixel PX_R, the second color pixel PX_G, and the third color pixel PX_B in the second direction DR2 may be minimized.

The electronic device having the above-described or like configuration may provide driving voltages having different voltage levels for the different colors of pixels, respectively. Accordingly, optimized driving voltages may be provided for each of the different colors of pixels. Thus, the power consumption of the electronic device may be minimized.

While the present disclosure has been described with reference to embodiments thereof, it will be apparent to those of ordinary skill in the pertinent art that various changes and modifications may be made thereto without departing from the scope and spirit of the present disclosure as set forth in the following claims.

What is claimed is:

1. An electronic device for displaying a multi-color image, the electronic device comprising:
a first bus line configured to supply a first driving voltage;
a second bus line configured to supply a second driving voltage different than the first driving voltage;
a first color pixel connected to the first bus line and configured to receive the first driving voltage and emit a first color of the multi-color image; and
a second color pixel connected to the second bus line and configured to receive the second driving voltage and emit a second color of the multi-color image different than the first color.

2. The electronic device of claim 1, wherein the first driving voltage comprises a first high voltage and the second driving voltage comprises a second high voltage, the electronic device further comprising:
a third bus line configured to supply a third high voltage different than the second high voltage; and
a third color pixel connected to the third bus line and configured to receive the third high voltage and emit a third color of the multi-color image different than each of the first color and the second color,
wherein the first bus line comprises a first vertical bus line configured to transfer the first high voltage and a first horizontal bus line configured to connect the first vertical bus line to the first color pixel,
wherein the second bus line comprises a second vertical bus line configured to transfer the second high voltage and a second horizontal bus line configured to connect the second vertical bus line to the second color pixel,
wherein the third bus line comprises a third vertical bus line configured to transfer the third high voltage and a third horizontal bus line configured to connect the third vertical bus line to the third color pixel.

3. The electronic device of claim 2,
wherein the first horizontal bus line, the second horizontal bus line, and the third horizontal bus line extend in a first direction and are spaced apart from each other in a second direction different from the first direction,
wherein the first vertical bus line, the second vertical bus line, and the third vertical bus line extend in the second direction and are spaced apart from each other in the first direction.

4. The electronic device of claim 2, wherein each of the first horizontal bus line, the second horizontal bus line, and the third horizontal bus line extends in a first direction,
wherein at least a portion of the first horizontal bus line and at least a portion of the second horizontal bus line are disposed to overlap each other when viewed from above a plane, and
wherein the first horizontal bus line and the third horizontal bus line are spaced apart from each other in a second direction different from the first direction.

5. The electronic device of claim 4, wherein the first vertical bus line, the second vertical bus line, and the third vertical bus line extend in the second direction and are spaced apart from each other in the first direction.

6. The electronic device of claim 2, wherein the first high voltage, the second high voltage, and the third high voltage have different voltage levels.

7. The electronic device of claim 2, wherein each of the first color pixel, the second color pixel, and the third color pixel includes:
a fifth transistor including a first electrode, a second electrode, and a gate electrode, wherein the first electrode is connected to a corresponding one of a first high voltage line, a second high voltage line, and a third high voltage line configured to receive the first high voltage, the second high voltage, and the third high voltage, respectively;
a first transistor including a gate electrode, the first transistor being connected between the second electrode of the fifth transistor and a first node;
a sixth transistor including a gate electrode, the sixth transistor being connected between the first node and a second node; and
a light-emitting element connected between the second node and a low voltage line.

8. The electronic device of claim 7, wherein the first color pixel further includes a fourth transistor including a first electrode connected to a first initialization voltage line, a second electrode connected to the second node, and a gate electrode.

9. The electronic device of claim 8, wherein each of the second color pixel and the third color pixel further includes a fourth transistor including a first electrode connected to a second initialization voltage line, a second electrode connected to the second node, and a gate electrode.

10. The electronic device of claim 9, wherein a first initialization voltage provided to the first initialization voltage line and a second initialization voltage provided to the second initialization voltage line have different voltage levels.

11. An electronic device comprising:
a base layer;
a first transistor of a first color pixel emitting a first color of light disposed over the base layer, the first transistor including a first electrode;
a second transistor of a second color pixel emitting a second color of light different than the first color of light disposed over the base layer, the second transistor including a first electrode;
a first horizontal bus line and a second horizontal bus line disposed over the base layer and insulated from each other; and
a first vertical bus line and a second vertical bus line configured to transfer a first high voltage and a second high voltage, respectively, wherein the first vertical bus line and the second vertical bus line are insulated from each other and disposed in a layer different from a layer in which the first horizontal bus line and the second horizontal bus line are disposed,
wherein the first vertical bus line is electrically connected to the first electrode of the first transistor through the first horizontal bus line, and
wherein the second vertical bus line is electrically connected to the first electrode of the second transistor through the second horizontal bus line.

12. The electronic device of claim 11, further comprising:
a first high voltage line disposed between the base layer and the first transistor;
a first insulating layer disposed between the first high voltage line and the first transistor; and
a second insulating layer disposed between the first transistor and the first horizontal bus line,
wherein the first horizontal bus line is electrically connected to the first electrode of the first transistor through a contact hole configured to penetrate the second insulating layer.

13. The electronic device of claim 12, further comprising:
a third insulating layer disposed between the first horizontal bus line and the first vertical bus line,
wherein the first vertical bus line is electrically connected to the first horizontal bus line through a contact hole configured to penetrate the third insulating layer.

14. The electronic device of claim 12, wherein the first horizontal bus line is electrically connected to the first high voltage line through a contact hole configured to penetrate the first insulating layer and the second insulating layer.

15. The electronic device of claim 11, further comprising:
a first high voltage line disposed between the base layer and the first transistor and configured to overlap the first transistor;
a first insulating layer disposed between the first high voltage line and the first transistor;
a second insulating layer disposed between the first transistor and the first horizontal bus line;
a third insulating layer disposed on the first horizontal bus line; and
an intermediate insulating layer disposed between the third insulating layer and the first vertical bus line,
wherein the first vertical bus line is electrically connected to the first horizontal bus line through a contact hole configured to penetrate the intermediate insulating layer and the third insulating layer, and
wherein the first horizontal bus line is electrically connected to the first electrode of the first transistor through a contact hole configured to penetrate the second insulating layer.

16. The electronic device of claim 15, wherein the second vertical bus line is electrically connected to the second horizontal bus line through a contact hole configured to penetrate the intermediate insulating layer, further comprising:
a connecting line disposed on the second insulating layer and configured to overlap the second horizontal bus line,
wherein the second horizontal bus line is electrically connected to the connecting line through a contact hole configured to penetrate the third insulating layer,
wherein the connecting line is electrically connected to the first electrode of the second transistor through a contact hole configured to penetrate the second insulating layer.

17. The electronic device of claim 11, wherein the first horizontal bus line and the second horizontal bus line extend in a first direction and are spaced apart from each other in a second direction different from the first direction, and
wherein the first vertical bus line and the second vertical bus line extend in the second direction and are spaced apart from each other in the first direction.

18. The electronic device of claim 11, wherein each of the first horizontal bus line and the second horizontal bus line extends in a first direction,
wherein at least a portion of the first horizontal bus line and at least a portion of the second horizontal bus line are disposed to overlap each other when viewed from above a plane, and
wherein the first vertical bus line and the second vertical bus line extend in a second direction different from the first direction and are spaced apart from each other in the first direction.

19. The electronic device of claim 11, wherein the first high voltage and the second high voltage have different voltage levels.

20. An electronic device comprising:
a first bus line including a first vertical bus line and a first non-vertical bus line configured to supply a first driving voltage;
a second bus line including a second vertical bus line and a second non-vertical bus line configured to supply a second driving voltage different than the first driving voltage;
a first color pixel connected to the first non-vertical bus line and configured to receive the first driving voltage and emit a first color of the multi-color image; and
a second color pixel connected to the second non-vertical bus line and configured to receive the second driving voltage and emit a second color of the multi-color image,
wherein the second non-vertical bus line comprises a second horizontal bus line.
